(19) United States
(12) Patent Application Publication
(10) Pub. No.: US 2006/0266852 A1
(43) Pub. Date: Nov. 30, 2006

(54) Shower head

(76) Inventor: Hae-Moon Choi, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/372,053

(22) Filed: Mar. 10, 2006

(30) Foreign Application Priority Data
May 24, 2005 (KR) 2005-0043829

(51) Int. Cl. B05B 1/14

(52) U.S. Cl. 239/548; 239/398

(57) ABSTRACT

A shower head includes measures to secure a port of one plate of the shower head to another plate of the shower head. A first plate of the shower head may have a bottom surface, a recess in the center of the bottom surface, and a first through-hole extending from the center of the recess. A second plate includes a plate-like base, and the port. The port projects from the base and includes a body defining a first flow passageway in fluid communication with the first through-hole. The port also includes a plurality of flanges. Port fixing structure is provided on a lower surface of the first plate to clamp the flanges of the port to the first plate. Alternatively, the first plate may include a plate-like base and a port projecting from the base. The port has a male threaded part at its distal end. The second plate has a corresponding female threaded part in which the male threaded part of the port is received. Also, a gasket may be provided that enhances the seal between the port and the surface which the port abuts in the shower head.

### BACKGROUND OF THE INVENTION

1. Field of the Invention

The present invention relates to a shower head of apparatus for manufacturing semiconductor devices or the like, such as a chemical vapor deposition apparatus. More particularly, the present invention relates to a shower head of the type that supplies process gases onto a substrate in a process chamber without the process gases mixing in the shower head.

2. Description of the Related Art

In general, a semiconductor device may be manufactured on a semiconductor wafer by selectively and repeatedly subjecting the wafer to various processes such as photolithography, etching, diffusion, chemical vapor deposition, ion injection, and metallization processes. In particular, equipment for performing the chemical vapor deposition process includes a vessel having a member for supporting a semiconductor wafer, and a shower head for supplying process gases to form a layer on a surface of the wafer. The shower head supplies the process gases onto the surface of the wafer while the process gases diffuse without mixing with each other in the shower head. To this end, the shower head includes three stages of metal plates fixed to each other by bolts and mounted to the vessel. The metal plates define discrete passageways for the process gases.

However, if the metal plates are not tightly secured to each other, the different kinds of process gases will mix with each other in the shower head. As a result, the process gases undergo a chemical reaction and thereby produce undesired by-products. These by-products may be in the form of particles, i.e., contaminants that cause defects in the process being carried out on the wafer.

Korean Patent Laid-open Publication No. 2004-86392, entitled “GAS SHOWER HEAD, FILM FORMING DEVICE AND FLIM FORMING METHOD,” filed by Murakami Seisi et al., discloses a shower head aimed at avoiding the problems described above. FIG. 1 is a sectional view of the shower head of Seisi et al, and FIG. 2 is an exploded sectional view of the shower head.

As shown in FIGS. 1 and 2, the shower head 3 includes three metal plates 3a, 3b and 3c, which will be referred to hereinafter as an upper plate 3a, an intermediate plate 3b, and a lower plate 3c. The upper plate 3a and the intermediate plate 3b are fixed to each other by first bolts 34a, and the intermediate plate 3b and the lower plate 3c are fixed to each other by second bolts 34b.

Also, the upper plate 3a is connected to first and second process gas supply pipes 21 and 22 through which respective process gases are supplied to the shower head. Furthermore, a first process gas receiving space 31 is formed between the upper plate 3a and the intermediate plate 3b, and a second process gas receiving space 41 is formed between the intermediate plate 3b and the lower plate 3c.

The intermediate plate 3b defines a plurality of first process gas flow passageways 32 in fluid communication with the first process gas receiving space 31, and a port 30 in fluid communication with the second process gas receiving space 41. The port 30 is discrete from, i.e., is not in fluid communication with, the first process gas receiving space 31.

The lower plate 3c has a plurality of first holes 33 in fluid communication with the first process gas flow passageways 32, and a plurality of second holes 43 in fluid communication with the second process gas receiving space 41.

When the shower head is assembled, the plates 3a, 3b and 3c are heated as the bolts 34a, 34 are tightened to create seals between the upper and intermediate plates 3a and 3b, and between the intermediate and lower plates 3b and 3c. More specifically, while the plates are under a pressure of about 30 kg/cm², the plates are heated at a temperature of 500˜550° C. for 12 hours, for example. As a result, contact surfaces of the plates are bonded by a local diffusion of metal while the bolts are being tightened. Also, the shower head 3 is disassembled after a predetermined number of processes are performed in the process chamber so that the interior of the showerhead can be cleaned. In this case, the shower head 3 should be disassembled under conditions similar to those described above in connection with the assembling of the shower head.

However, the shower head 3 may have the following problems.

First, the assembling or disassembling of the shower head 3 is very troublesome and time-consuming because specific conditions, as described above, must be created and maintained when assembling and dissembling the shower head.

Second, the port 30 of the intermediate plate 3b may not be perfectly fitted to a surface P1 of the upper plate 3a when the shower head 3 is assembled. Furthermore, gaps may be created between the port 30 and the surface P1 due to thermal deformation of the intermediate plate 3b and/or the lower plate 3c.

### SUMMARY OF THE INVENTION

Therefore, an object of the present invention is to overcome the problems presented in the prior art described hereinabove.

More specifically, an object of the present invention is to provide a shower head capable of facilitating its assembly and disassembly.

Another object of the present invention is to provide a shower head that ensures that different kinds of process gases will not mix with each other in the shower head.

According to one aspect of the present invention there is provided a shower head having a first plate, a second plate confronting a lower surface of the first plate and having a port that includes a plurality of flanges, and port fixing structure disposed on a lower surface of the first plate and clamping the flanges of the port to the first plate. The first plate also has a recess at the center of its lower surface, and a first through-hole extending from the center of the recess. The port of the second plate is received in the recess in the lower surface of the first plate. The port has a body, and the flanges extend from a distal end of the body. The body of the port defines a first flow passageway that extends therethrough and is in fluid communication with the first through-hole.

The first plate may also have a second through-hole. Furthermore, the first plate may be configured with and fastened to the second plate such that a second gas receiving space is formed between the first and second plate. Thus, a second gas introduced through the second through-hole will diffuse in the second gas receiving space.

The second plate may also define a first gas receiving space in fluid communication with the first through-hole and the first flow passageway. Thus, a first gas introduced through the first through-hole and the first flow passageway will diffuse in the first gas receiving space. The second plate may also have a plurality of second flow passageways extending therethrough in fluid communication with the second gas receiving space.

In addition, a third plate may be disposed on the side of the second plate opposite the first plate. The third plate may have a plurality of first ejection holes in fluid communication with the first gas receiving space, and a plurality of second ejection holes in fluid communication with the second flow passageways.

Furthermore, each of the flanges may have a surface, at a side thereof facing the port fixing structure, which is inclined in the circumferential direction of the second plate. Alternatively, the port fixing structure has a plurality of surfaces, at a side thereof facing the flanges, which are each inclined in the circumferential direction of the second plate. The inclined surfaces facilitate the hooking of the flanges by the port fixing structure when the first and second plates are rotated relative to each other during their assembly.

In accordance with another aspect of the invention, there is provided a shower head comprising a first plate including a plate-like base and a port integral with and projecting from the base plate, and a second plate to which the port is threaded. The port has a male threaded part at a distal end thereof, and the second plate has a female threaded part in which the male threaded part of the port is received. The base of the first plate has a first through-hole. The port defines a first flow passageway extending therethrough in fluid communication with the first through-hole. The second plate defines a first gas receiving space therein in fluid communication with the first flow passageway extending through the port.

According to still another aspect of the invention, a gasket is interposed between the port and the surface of the plate against which the port rests. The gasket is annular, and has a substantially C-shaped cross section. The gasket also has projections extending in the axial direction of the gasket from outer peripheries of upper and lower surfaces thereof, respectively.

### BRIEF DESCRIPTION OF THE DRAWINGS

The foregoing and other objects, features and advantages of the invention will be apparent from the detailed description of the preferred embodiments of the invention, as illustrated in the accompanying drawings. The drawings, though, are not necessarily to scale.

FIG. 1 is a sectional view of a conventional shower head.

FIG. 2 is an exploded sectional view of the shower head shown in FIG. 1.

FIG. 3 is a sectional view of a first embodiment of a shower head in accordance with the present invention.

FIG. 4A is an exploded perspective view of a port of a second plate and a gasket of the shower head shown in FIG. 3.

FIG. 4B is a cross-sectional view of the gasket taken along line I-I′ of FIG. 4A.

FIGS. 4C and 4D are each a cross-sectional view of a portion the shower head illustrating the structure in which the port shown in FIG. 4A is fastened to the first plate.

FIGS. 5A and 5B are plan views of another form of a port and a port fixing of a shower head in accordance with the present invention.

FIG. 6A is a sectional view of a second embodiment of a shower head in accordance with the present invention.

FIG. 6B is an enlarged view of the encircled portion A of the showerhead shown in FIG. 6A.

FIG. 7A is a sectional view of a third embodiment of a shower head in accordance with the present invention.

FIG. 7B is an enlarged view of encircled portion B of the shower head shown in FIG. 7A.

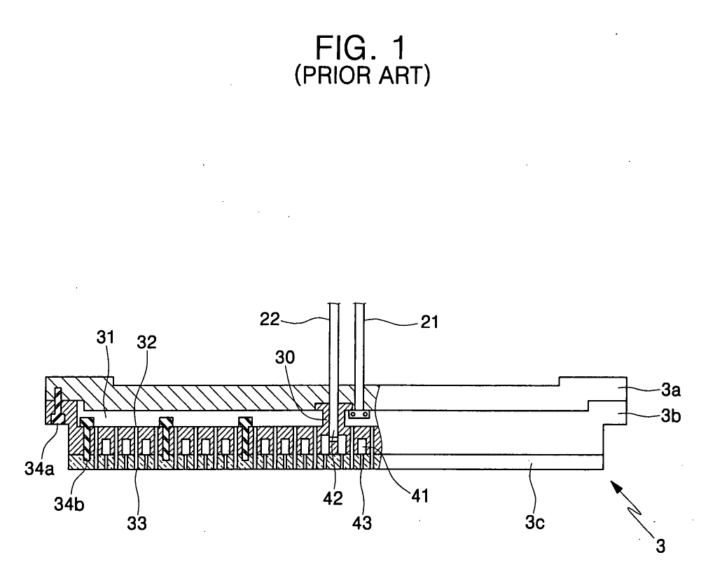

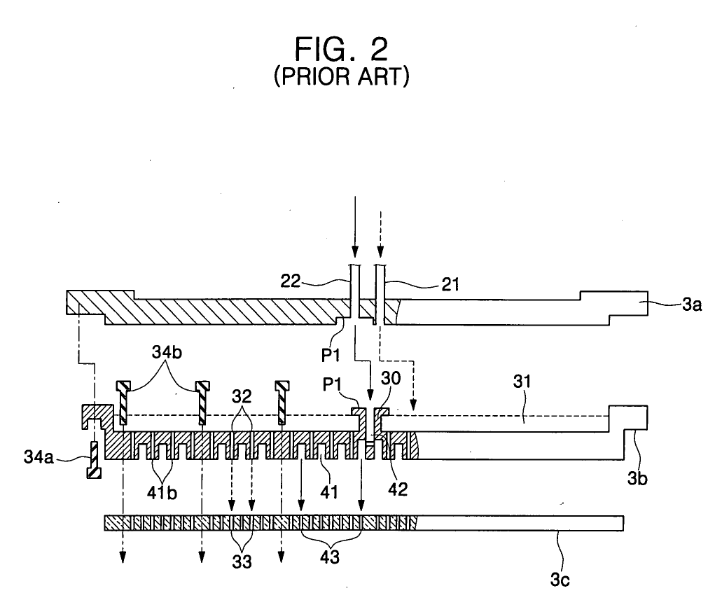

### DETAILED DESCRIPTION OF THE PREFERRED EMBODIMENTS

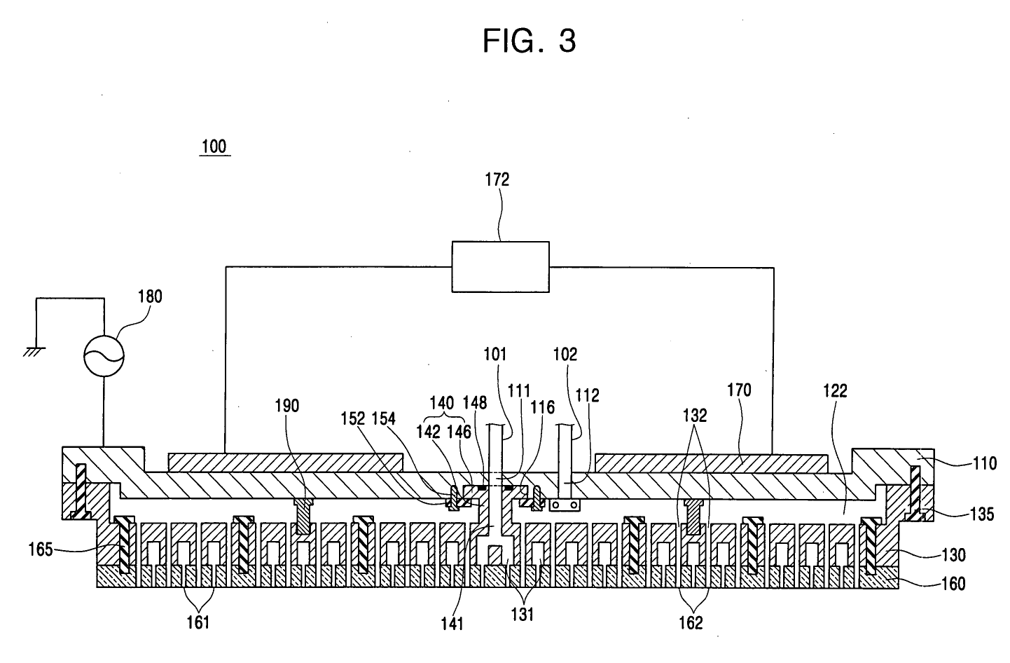

The preferred embodiments of a shower head in accordance with the present invention will be described in detail hereinafter with reference to the drawings of FIGS. 3-7B. For the most part, like reference numerals designate like elements throughout the drawings.

Referring first to FIG. 3, a first embodiment of the shower head 100 includes first, second and third metal plates 110, 130 and 160 stacked one atop the other. The first, second and third plates 110, 130 and 160 are each of a material that will not react with process gases. For example, each of the plates 110, 130 and 160 are of nickel or a nickel alloy having good thermal resistance and corrosion resistance.

The first plate 110 has a recess 116 in the center of its bottom surface, and a first through-hole 111 extending from the center of the recess 116. A first gas supply pipe 101 extends to the through-hole 111 and is attached to the first plate 110. In addition, the first plate 110 includes a second through-hole 112, and a second gas supply pipe 102 extends to the second through-hole and is attached to the first plate 110.

The second plate 130 and the first plate 110 fit together such that a second gas receiving space 122 is left between the first and second plates 110 and 130. A second gas supplied into the second gas receiving space 122 via the second through-hole 112 diffuses horizontally within the space 122. Also, the first and second plates 110 and 130 are fastened by a plurality of bolts 135. In addition, the second plate 130 defines a plurality of second flow passageways 132 in fluid communication with the second gas receiving space 122, and a first gas receiving space 131. A first gas supplied into the first gas receiving space 131 via the first through-hole 111 diffuses horizontally within the space 131. The second plate 130 also has a port 140 that is received in the recess 116 and is held securely to the first plate 110 by a port fixing structure comprising port fixing members 152.

The third plate 160 is fastened to the second plate 130 by bolts 165. The third plate 160 has a plurality of first ejection holes 161 extending therethrough in fluid communication with the first gas receiving space 131, and second ejection holes 162 extending therethrough in fluid communication with the second flow passageways 132.

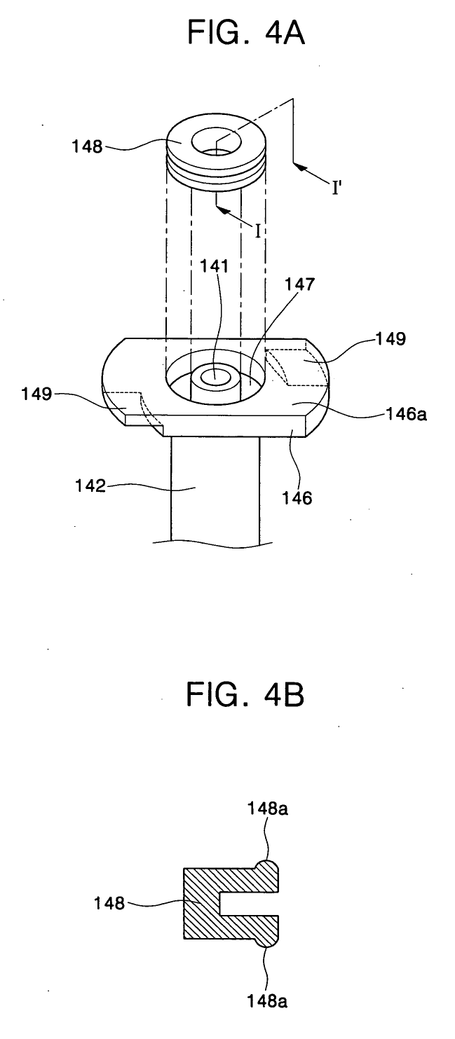

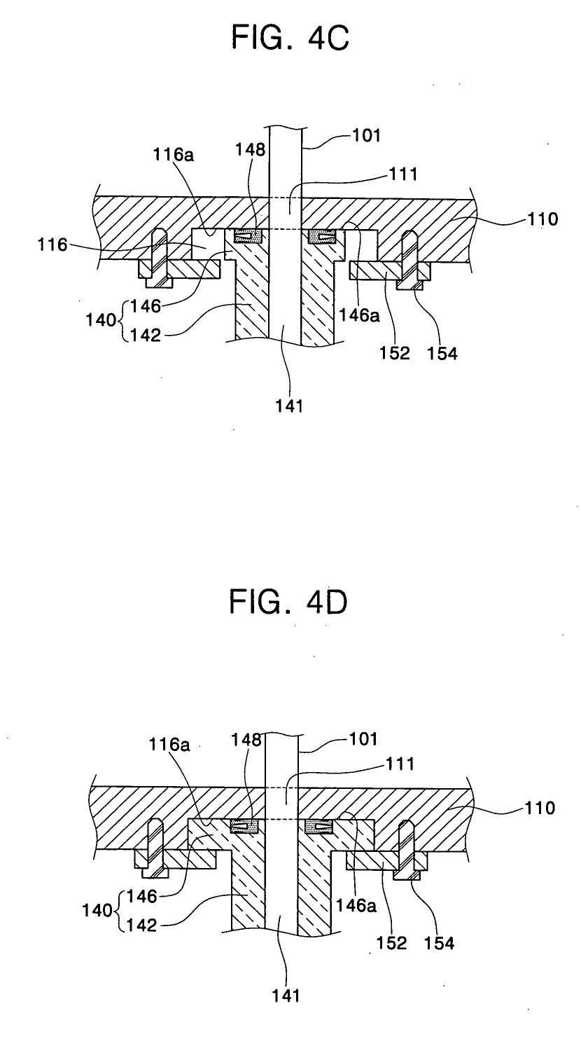

Referring to FIGS. 3, and 4A to 4D, the port 140 of the second plate 130 includes a body 142 defining a first flow passageway 141 communicating with the first through-hole 111 and the first gas receiving space 131. The port 140 also has two flanges 146 extending horizontally at both sides of the upper portion of the body 142.

The port fixing members 152 engage the flanges 146 to fix the port 140 to the first plate 110 with an upper surface 146a of the port 140 butted against a surface 116a of the first plate 110 that defines the bottom of the recess 116. The port fixing members 152 are fastened to the bottom surface of the first plate 110 by bolts 154.

In addition, a gasket 148 is interposed between the surface 116a of the first plate 110 that defines the bottom of the recess 116, and the upper surface 146a of the port 140 to prevent the first gas, which is introduced into the first flow passageway 141 from the first through-hole 111, from leaking into the second gas receiving space 122. The gasket 148 is annular and has a substantially C-shaped cross section, and projections 148a extending from the outer peripheries of its upper and lower surfaces in the axial direction of the gasket (i.e., upwardly and downwardly). The gasket 148 inserted into a gasket receiving groove 147 extending in the upper surface 146a of the port 140. The gasket 148 has a thickness greater than the depth of the gasket receiving groove 147. Therefore, one of the projections 148a of the gasket 148 initially projects slightly above the level of the upper surface 146a of the port 140 when the gasket 148 is inserted into the gasket receiving groove 147. However, the gasket 148 is compressed when the upper surface 146a of the port 140 is pressed against the surface 116a of the first plate 110. As a result, the projections 148a are urged against the port 140 and the surface 116a of the first plate 116a to effectively seal the interface, i.e., to seal the second gas receiving space 122 from the first through-hole 111. The gasket 148 is of a metal having good heat and corrosion resistance so as to withstand temperatures of more than 360° C., and gases present in the environment in which the shower head 100 operates. Therefore, the gasket 148 is preferably of nickel.

Next, the process of fastening the port 140 to the first plate 110 will be described. First, as shown in FIG. 4C, the port 140 is inserted into the recess 116 in the bottom surface of the first plate 110 and the upper surface 146a of the port 140 is placed against the surface 116a of the first plate 110 that defines the bottom of the recess 116. Next, the second plate 130 is rotated in a predetermined direction to rotate the port 140 and thereby hook the flanges 146 of the port 140 on the port fixing members 152, as shown in FIG. 4D. Moreover, each flange 146 has a surface 149, at a side thereof facing a port fixing member 152, which is inclined in the circumferential direction of the second plate 130 (direction of rotation) beginning at an edge of the flange. Thus, the flanges 146 can easily slide under and then ride up on the port fixing members 152 when the second plate 130 and port 140 are rotated. Alternatively, the port fixing members 152 may have similar inclined surface at upper sides thereof, i.e., those facing the flanges 146.

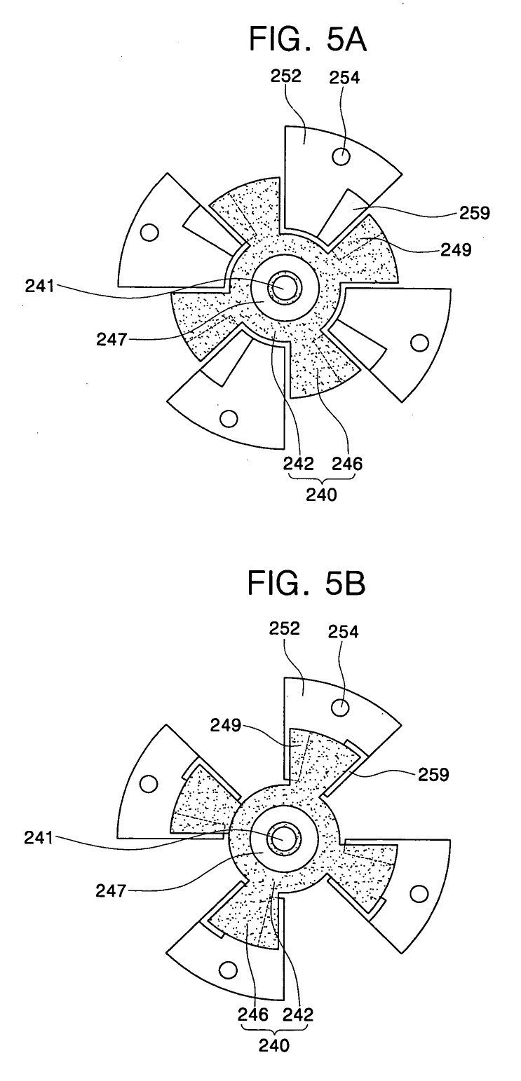

FIGS. 5A and 5B illustrate another form of the port of the second plate of the shower head shown in FIG. 3 and the structure for fixing the port to the first plate.

Referring to FIGS. 3, 5A and 5B, the port 240 of the second plate 130 includes a body 242 defining a first flow passageway 241 communicating with the first through-hole 111 and the first gas receiving space 131. In addition, the port 240 has four flanges 246 extending horizontally in four directions from the upper part of the body 242.

The port 240 is received in the recess space 116 in the bottom surface of the first plate 110 as secured thereto by port fixing members 252. The port fixing members 252 are fastened to the lower surface of the first plate 110 by bolts 254.

A gasket 248 is interposed between the surface 116a of the first plate 110 that defines the bottom of the recess space 116, and the upper surface of the port 240 to prevent a first gas which is introduced into the first flow passageway 241 from the first through-hole 111 from leaking into the second gas receiving space 122. The gasket 248 is received in a gasket receiving groove 247 extending in the upper surface of the port 240. The shape, material and function of the gasket 248 are similar to those of the gasket 148 and thus, no further description thereof will be made.

However, the process of fastening the port 240 to the first plate 110 will be described. First, as shown in FIG. 5A, the port 240 is inserted into the recess 116. Next, the port 240 and second plate 130 are rotated in a predetermined direction to hook the flanges 246 under the port fixing members 252, as shown in FIG. 5B. Moreover, lower portions 249 of the flanges 246 (or upper portions of the port fixing members 252) are inclined in the direction of rotation so that the flanges 246 can easily slide under and then ride up on the port fixing members 252 when the second plate 130 and port 140 are rotated. Accordingly, the port 240 is fastened to the first plate 110 in a state in which the upper surface of the port 240 is pressed tightly against the surface 116a of the first plate 110 that defines the bottom of the recess 116.

As described above, the shower head 100 in accordance with the present invention can be readily assembled and disassembled. In addition, the port 140 or 240 is securely fixed to the first plate 110 to prevent a gap from being created in the shower head 100, especially between the first plate 110 and the port 140 (or 240) of the second plate 130. Therefore, the first gas can be prevented from mixing with the second gas in the shower head. Therefore, by-products which might otherwise act as contaminants, are prevented from being produced in the shower head.

Referring again to FIG. 3, a heater 170 may be installed on the first plate 110 to provide the temperature required to perform the process on the wafer in the process chamber. A controller 172 is connected to the heater 170 to control the operation of the heater 170. Typically, the atmosphere in a space between the shower head 100 and the wafer is heated to a temperature of more than about 360° C. to facilitate the reaction of the process gases. However, if there is a large difference between the temperature of the process gases in the first and second gas supply pipes 101 and 102 of the shower head and the temperature of the atmosphere between the shower head and the wafer, some of the process gases could condense in the shower head 100. in such a case the process gases would not react properly, or other process failures would occur. Therefore, the heater 170 is operated by the controller 172 to prevent temperature differences from arising between the initial temperature of the process gases injected into the shower head 100 and the temperature of the atmosphere within the space between the shower head and the wafer, and to adjust the temperature of the atmosphere between the shower head and the wafer.

In addition, a radio frequency (RF) power source 180 may be connected to the first plate 110 for applying RF power that converts the process gases supplied by the shower head into plasma. In this case, specific ions in the plasma are deposited onto the wafer. Furthermore, a plurality of auxiliary power transmission members 190 may be interposed between the first and second plates 110 ad 130 to facilitate the transmitting of the RF power applied to the first plate 110 to the second and third plates 130 and 160. The auxiliary power transmission members 190 may be bolts of conductive material threaded to the second plate 130 such that the heads of the bolts contact the bottom surface of the first plate 110.

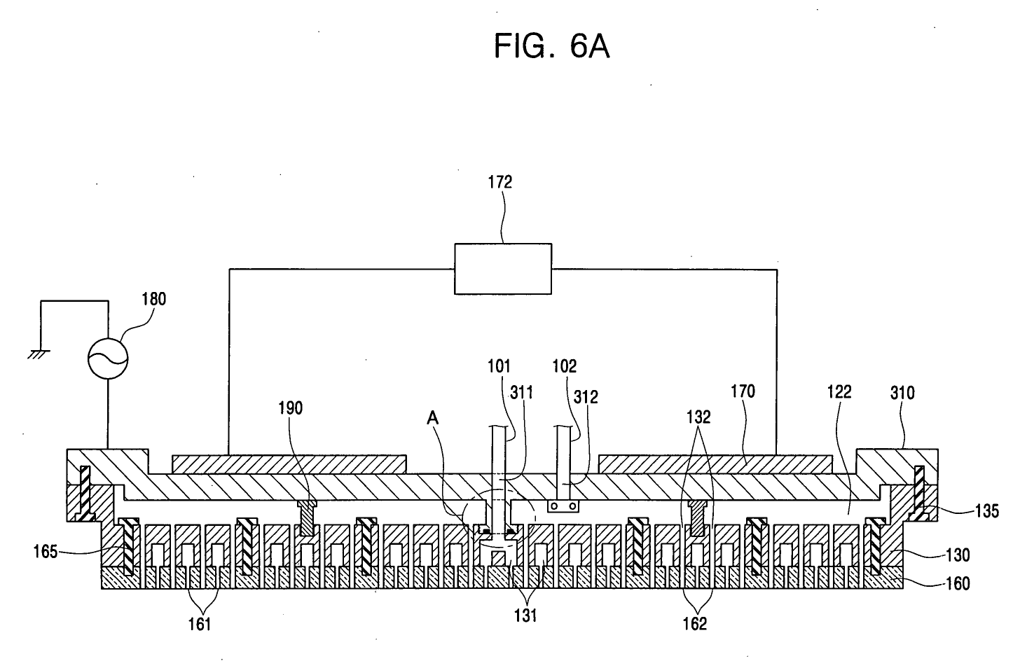

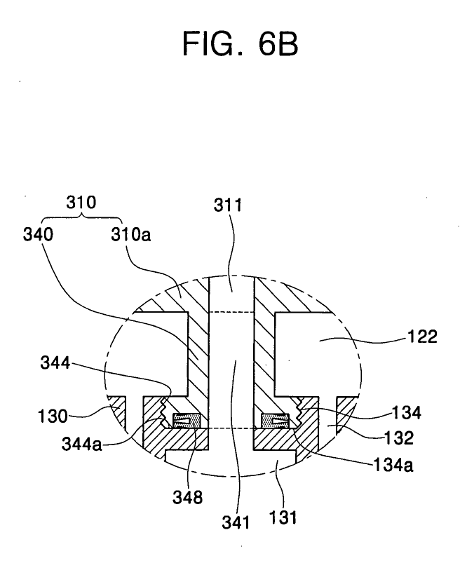

A second embodiment of a shower head in accordance with the present invention will now be described with reference to FIGS. 6A and 6B. However, a detailed description of those elements that are similar to the first embodiment, and are designated by the same reference numerals, will be omitted.

The shower head includes a first plate 310 that includes a plate-like base 310a, and a port 340 integral with the base 310a. The port 340 is to be threaded to a second plate 130. More specifically, the port 340 projects from a lower surface of the base 310a. The port 340 has a body that defines a first flow passageway 341 extending therethrough. In addition, the port 340 includes a male threaded part 344 at its distal end. The male threaded part 344 is threaded to a corresponding female threaded part 134 of the second plate 130. As a result, the first flow passageway 341 is in fluid communication with a first gas receiving space 131 in the second plate 130.

The first plate 310 also has a first through-hole 311 in fluid communication with the first flow passageway 341 and to which a first gas supply pipe 101 is connected. In addition, the base 310a of the first plate 310 has a second through-hole 312 in fluid communication with a second gas receiving space 122 and to which a second gas supply pipe 102 is connected.

Moreover, a gasket 348 is interposed between a lower surface 344a of the male threaded part 344 of the port 340 and a bottom surface 134a of the female threaded part 134 of the second plate 130 to prevent a first gas flowing through the first flow passageway 341 from leaking into the second gas receiving space 122. In this respect, the shape, material and function of the gasket 348 are similar to those of the gasket 148 shown in FIGS. 4A to 4C and thus, a detailed descriptions thereof will be omitted.

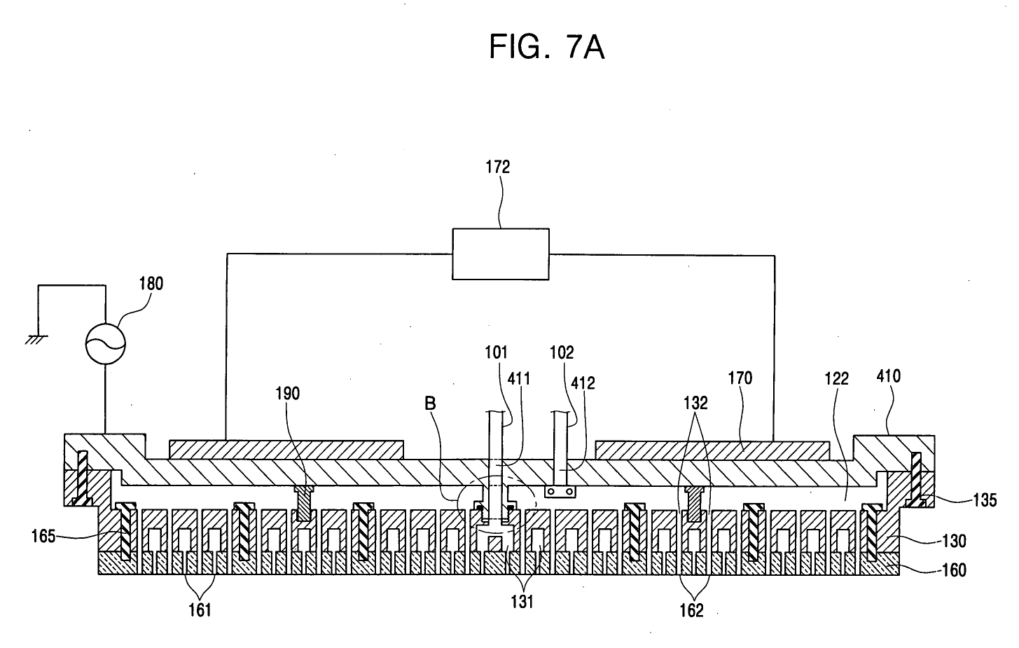

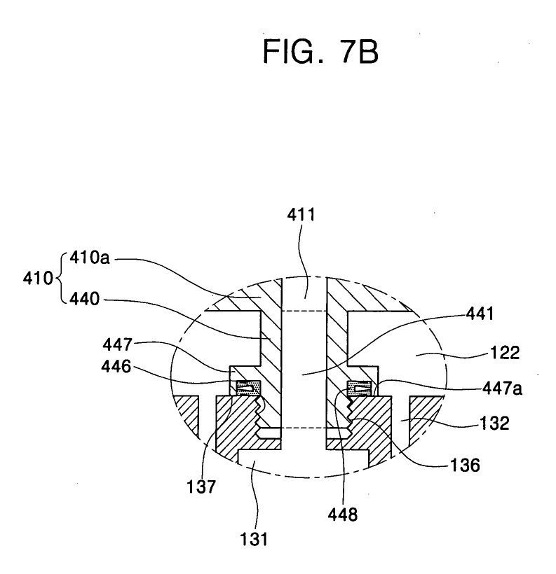

A third embodiment of a shower head in accordance with the present invention will now be described with reference to FIGS. 7A and 7B. However, elements that are similar to those of the first embodiment, and designated by the same reference numerals, will not be described in further detail.

The shower head includes a first plate AA1 including a plate-like base 410a and a port 440 projecting from a lower surface of the base 410a. The port 440 has a body defining a first flow passageway 441 extending vertically therethrough. The first flow passageway 441 is in fluid communication with a first gas receiving space 131 in the second plate 130. In addition, the port 440 has a male threaded part 446 at a distal end thereof. The male threaded part 446 is threaded to a corresponding female threaded part 136 of a second plate 130. The port 440 also includes an annular flange 447. A lower surface 447a of the flange 447 abuts an upper surface 137 of the second plate 130.

Moreover, the base 410a of the first plate 410 has a first through-hole 411 in fluid communication with the first flow passageway 441 and to which a first gas supply pipe 101 is connected. In addition, the base 410a of the first plate 410 has a second through-hole 412 in fluid communication with a second gas receiving space 122 and to which a second gas supply pipe 102 is connected.

Furthermore, a gasket 448 is interposed between a lower surface 447a of the flange 447 of the port 440 and an upper surface 137 of the second plate 130 to prevent the first gas introduced through the first flow passageway 441 from leaking into the second gas receiving space 122. In this respect, the shape, material and function of the gasket 448 are similar to those of the gasket 148 shown in FIGS. 4A to 4C and thus, detailed descriptions thereof will be omitted.

According to the present invention as described above, the shower can be readily assembled or disassembled. In addition, a gap is prevented from being created in the shower head, especially between the port and the plate that receives the port. Still further, a gasket enhances the seal between the port and the plate that receives the port. As a result, process gases are not mixed in the shower head. Therefore, by-products which might otherwise contaminate the substrate being processed, are prevented from being produced in the shower head.

Although the present invention has been described in connection with the preferred embodiments thereof, it is to be understood that the invention is not limited to the disclosed embodiments. Rather, various changes to and modifications of the preferred embodiments are within the true spirit and the scope of the invention as set forth in the appended claims.

What is claimed is:

1. A shower head comprising:
a first plate having an upper surface, a lower surface, a recess at the center of the lower surface, and a first through-hole extending from the center of the recess;
a second plate disposed against the first plate, the second plate including a base plate and a port projecting from the base plate, the port received in the recess in the lower surface of the first plate, the port having a body, and a plurality of flanges extending from a distal end of the body, and the body of the port defining a first flow passageway that extends therethrough and is in fluid communication with the first through-hole; and
port fixing structure disposed on the lower surface of the first plate and clamping the flanges to the first plate.

2. The shower head according to claim 1, wherein the second plate defines a first gas receiving space in fluid communication with the first flow passageway, whereby a first gas introduced through the first through-hole and the first flow passageway will diffuse in the first gas receiving space.

3. The shower head according to claim 2, wherein the first plate has a second through-hole, and is configured with and fastened to the second plate such that a second gas receiving space is formed between the first and second plates, the second gas receiving space being in fluid communication with the second through-hole, whereby a second gas introduced through the second through-hole will diffuse in the second gas receiving space.

4. The shower head according to claim 3, wherein the second plate defines a plurality of second flow passageways extending therethrough in fluid communication with the second gas receiving space.

5. The shower head according to claim 4, further comprising a third plate disposed on a side of the second plate opposite the first place, and defining a plurality of first ejection holes in fluid communication with the first gas receiving space and a plurality of second ejection holes in fluid communication with the second flow passageways.

6. The shower head according to claim 1, wherein at least four of the flanges extend from the distal end of the body of the port.

7. The shower head according to claim 1, wherein each of the flanges has a surface, at a side thereof facing a port fixing structure, which is inclined in the circumferential direction of the second plate.

8. The shower head according to claim 1, wherein the port fixing structure has a plurality of surfaces, at a side thereof facing the flanges, which are each inclined in the circumferential direction of the second plate.

9. The shower head according to claim 1, further comprising a gasket interposed between an upper surface of the port and a surface of the first plate that defines the bottom of the recess.

10. The shower head according to claim 9, wherein the gasket is annular, has a substantially C-shaped cross section, and projections extending in the axial direction of the gasket from outer peripheries of upper and lower surfaces thereof, respectively.

11. The shower head according to claim 1, further comprising a heater disposed on the first plate.

12. The shower head according to claim 1, further comprising a high frequency power source connected to the first plate.

13. The shower head according to claim 12, further comprising a plurality of auxiliary power transmission members interposed between the first and second plates, the transmission members each comprising an electrically conductive material.

14. A shower head comprising:
a first plate including a plate-like base having a first through-hole, and a port integral with and projecting from the base plate, the port having a male threaded part at a distal end thereof, and the port defining a first flow passageway extending therethrough, the first flow passageway being in fluid communication with the first through-hole; and
a second plate having a female threaded part to which the male threaded part of the port is threaded, and the second plate defining a first gas receiving space therein in fluid communication with the first flow passageway extending through the port.

15. The shower head according to claim 14, wherein the base of the first plate also has a second through-hole, and is configured with and fastened to the second plate such that a second gas receiving space is formed between the first and second plates, the second gas receiving space being in fluid communication with the second through-hole, whereby a second gas introduced through the second through-hole will diffuse in the second gas receiving space.

16. The shower head according to claim 15, wherein the second plate also has a plurality of second flow passageways extending therethrough in fluid communication with the second gas receiving space.

17. The shower head according to claim 16, further comprising a third plate disposed on a side of the second plate opposite the first plate, and having a plurality of first ejection holes in fluid communication with the first gas receiving space and a plurality of second ejection holes in fluid communication with the second flow passageways.

18. The shower head according to claim 16, further comprising a gasket interposed between an end surface of the distal of the port and a surface at an end of the female threaded part of the second plate.

19. The shower head according to claim 18, wherein the gasket is annular, and has a substantially C-shaped cross section, and projections extending in the axial direction of the gasket from outer peripheries of upper and lower surfaces thereof, respectively.

20. The shower head according to claim 14, wherein the port further comprises an annular flange, and a major surface of the flange abutting the second plate.

21. The shower head according to claim 20, further comprising a gasket interposed between the flange and the second plate.

22. The shower head according to claim 21, wherein the gasket is annular, and has a substantially C-shaped cross section, and projections extending in the axial direction of the gasket from outer peripheries of upper and lower surfaces thereof, respectively.

23. The shower head according to claim 14, further comprising a heater disposed on the first plate.

24. The shower head according to claim 14, further comprising a high frequency power source connected to the first plate.

25. The shower head according to claim 24, further comprising a plurality of auxiliary power transmission members interposed between the first and second plates, the auxiliary transmission members each comprising an electrically conductive material.
